(19) United States
(12) Patent Application Publication
(10) Pub. No.: US 2021/0257790 A1
(43) Pub. Date: Aug. 19, 2021

(54) INFORMATION PROCESSING APPARATUS

(71) Applicant: PANASONIC INTELLECTUAL PROPERTY MANAGEMENT CO., LTD., Osaka (JP)

(72) Inventors: Takeyuki SASAKI, Kanagawa (JP); Kyohei KIDA, Kanagawa (JP)

(73) Assignee: PANASONIC INTELLECTUAL PROPERTY MANAGEMENT CO., LTD., Osaka (JP)

(21) Appl. No.: 17/116,786

(22) Filed: Dec. 9, 2020

(30) Foreign Application Priority Data
Feb. 13, 2020 (JP) 2020-022596

(51) Int. Cl. H01R 13/66; H01R 12/73; H01R 13/52; H05K 1/02; H05K 1/18; G06K 7/00

(52) U.S. Cl. CPC H01R 13/6683; H01R 12/73; H01R 13/5213; H05K 1/0275; H01R 2201/06; G06K 7/0056; H05K 2201/10151; H05K 2201/10189; H05K 2201/0999; H05K 1/181

(57) ABSTRACT

An information processing apparatus includes a card slot; a circuit board; a flat card connector mounted on a main face of the circuit board; a first contact provided on the main face of the circuit board; a cover covering the card connector and the first contact on the circuit board; a second contact provided on a bottom face of the cover and contacting the first contact; a tampering detection wiring for tampering detection arranged on the cover and connected to the second contact; and an opening formed at a front end of the cover lager than an opening of the card slot. The cover is shaped so that a height from the circuit board to an area with the second contact on the bottom face of the cover is lower than a height from the circuit board to a top face of the card connector.

### CROSS-REFERENCE TO RELATED APPLICATIONS

This application is based on and claims priority under 35 USC 119 from Japanese Patent Application No. 2020-022596 filed on Feb. 13, 2020, the contents of which are incorporated herein by reference.

### TECHNICAL FIELD

The present disclosure relates to an information processing apparatus.

### BACKGROUND ART

In recent years, the introduction of settlement terminals that provide electronic settlements to users has been promoted in stores and commercial facilities. The settlement terminals handle secret information such as a credit card number, identification information of an IC card, personal information of a user, and a secret key used for encrypting information in the internal processing. Therefore, the information processing apparatus that executes the internal processing of the settlement terminal includes a tamperproof mechanism for resisting a physical attack (tamper) from the outside for the purpose of analyzing or falsifying secret information.

Patent Literature 1 discloses an information processing apparatus including first and second circuit boards disposed on a device main body in a state of being separated from each other, electronic components disposed on opposite faces of the first and second circuit boards respectively, a shielding member surrounding an outer periphery of the first and second circuit boards and including a detection line on an inner face, and a tamper detection unit. When the tamper detection unit detects a tamper based on a damage of a detection line, the tamper detection unit erases the data in the memory. As a result, the secret information in the memory is prevented from being analyzed.

Patent Literature 2 discloses a data storage device including sufficiently thin electric wires which are wired so as to cover almost the entire face of a housing at a sufficiently narrow interval, a tamper detection unit that detects disconnection of the electric wire, and a memory provided in the housing. The tamper detection unit erases the data in the memory in a case where the disconnection of the electric wire is detected. As a result, the secret information in the memory is prevented from being analyzed.

### CITATION LIST

### Patent Literature

Patent Literature 1: JP-A-2013-3979

Patent Literature 2: JP-A-2008-33593

### SUMMARY OF INVENTION

As described above, the information processing apparatus which handles secret information is required to have physical tamper proof. An object of the present disclosure is to provide an information processing apparatus with enhanced tamper proof.

An information processing apparatus according to the present disclosure includes a card slot that is arranged on a front of the information processing apparatus; a circuit board; a flat card connector that is mounted on a main face of the circuit board. A first contact is provided on the main face of the circuit board, and is disposed behind the card connector. A cover covers the card connector and the first contact on the circuit board. A second contact is provided on a bottom face of the cover, and is in contact with the first contact. A tampering detection wiring is arranged on the cover, is a wiring for tampering detection, and is connected to the second contact. An opening is formed at a front end of the cover lager than an opening of the card slot. The cover is shaped so that a height from the circuit board to an area with the second contact on the bottom face of the cover is lower than a height from the circuit board to a top face of the card connector.

According to the present disclosure, an information processing apparatus having improved tamper proof can be provided.

### BRIEF DESCRIPTION OF DRAWINGS

FIGS. 1A to 1C are views showing a configuration example of a settlement terminal according to the present embodiment, FIG. 1A is a top view, FIG. 1B is a side view, and FIG. 1C is a front view.

FIG. 2 is a view showing a configuration example of the information processing apparatus according to the present embodiment, and is a sectional view of the information processing apparatus as viewed from a left side.

FIG. 3 is a view showing a configuration example of a protective cover according to the present embodiment, and is a perspective view of the protective cover as viewed from a back side.

### DESCRIPTION OF EMBODIMENTS

Hereinafter, embodiments of the present disclosure will be described in detail with reference to the drawings as appropriate. However, unnecessarily detailed description may be omitted. For example, detailed description of well-known matters and repeated description of substantially the same configurations may be omitted. This is to avoid unnecessary redundancy in the following description and to facilitate understanding of those skilled in the art. The accompanying drawings and the following description are provided for those skilled in the art to fully understand the present disclosure, and are not intended to limit the subject matter of the claims.

(Present Embodiment)

<Settlement Terminal>

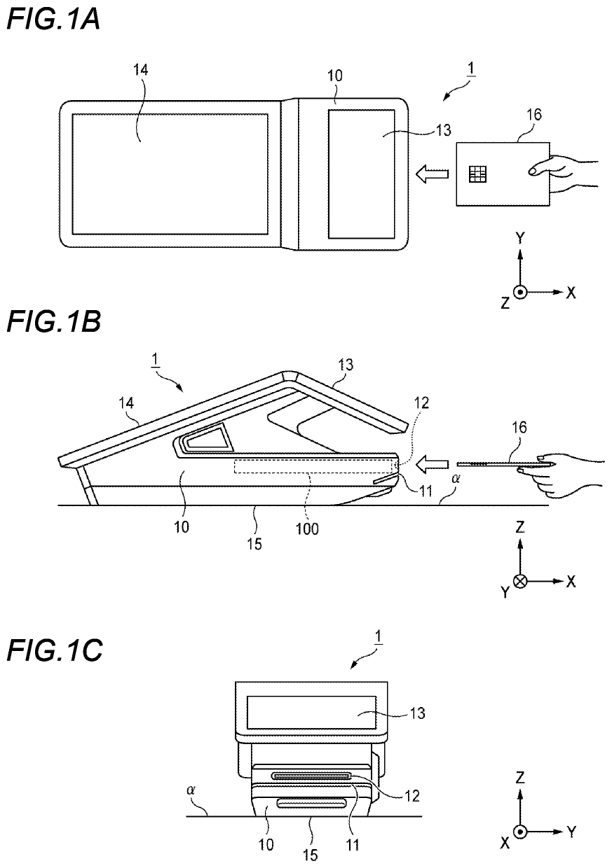

FIGS. 1A to 1C are views showing a configuration example of a settlement terminal according to the present embodiment, FIG. 1A is a top view, FIG. 1B is a side view, and FIG. 1C is a front view.

The settlement terminal 1 is a terminal corresponding to at least an electronic settlement, and is placed and used on a placement face a such as a counter of a store, for example. As shown in FIG. 1A, the settlement terminal 1 includes a substantially box-shaped housing 10.

The settlement terminal 1 may be a composite type settlement terminal capable of selecting a plurality of settlement methods by a user who performs electronic settlement. The settlement terminal 1 has a settlement mechanism for a user to select a settlement method and perform settlement. For example, as shown in FIG. 1C, the settlement terminal 1 includes, as a settlement mechanism, a slot 11 for settlement of a magnetic card, a slot 12 for settlement of a contact IC card, and a touch face 13 for contact-less settlement, in this order from a bottom face 15 upward on one end side of the housing 10. In addition, the settlement terminal 1 includes an operation mechanism for an employee and the like of the store to perform settlement approval and the like. For example, as shown in FIG. 1B, the settlement terminal 1 includes, as an operation mechanism, an operation screen 14 on the other end side of the housing 10 (that is, on the opposite side of the settlement mechanism).

For example, a user inserts and slides a magnetic card into the slot 11 for magnetic card settlement. The user inserts a contact IC card 16 into the slot 12 for settlement of the contact IC card. The user holds a contact-less type IC card over the touch face 13 for contact-less settlement. The employee of the store operates the operation screen 14 of the settlement terminal 1 to determine the card settlement of the user.

The settlement terminal 1 includes an information processing apparatus 100 for performing settlement processing inside the housing 10. The information processing apparatus 100 which handles secret information such as settlement processing is required to have high security against physical attacks from the outside. That is, the information processing apparatus 100 is required to have high tamper proof. The information processing apparatus 100 having improved tamper proof will be described below.

For convenience of description, as shown in FIGS. 1A to 1C, an axis perpendicular to the bottom face 15 of the housing 10 is defined as a Z axis. An axis perpendicular to the Z axis (that is, parallel to the bottom face of the housing 10) from the operation mechanism side to the settlement mechanism side of the housing 10 is defined as the X axis. An axis orthogonal to the X axis and the Z axis is defined as a Y axis. For convenience of description, there is a case where the positive direction of the X axis is referred to as “front”, the negative direction of the X axis is referred to as “rear”, the positive direction of the Y axis is referred to as “right”, the negative direction of the Y axis is referred to as “left”, the positive direction of the Z axis is referred to as “upper”, and the negative direction of the Z axis is referred to as “lower”. Note that the expressions relating to these directions are used for convenience of description and are not intended to limit the posture of the structure in actual use.

<Information Processing Apparatus>

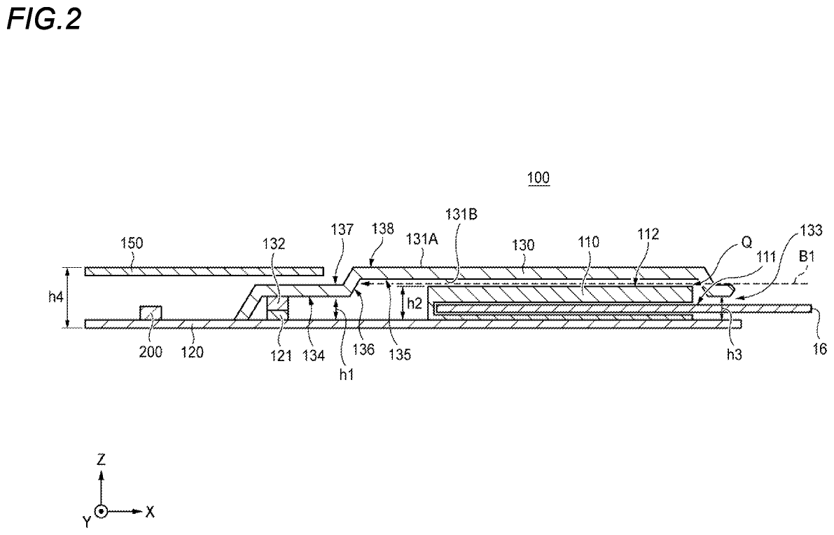

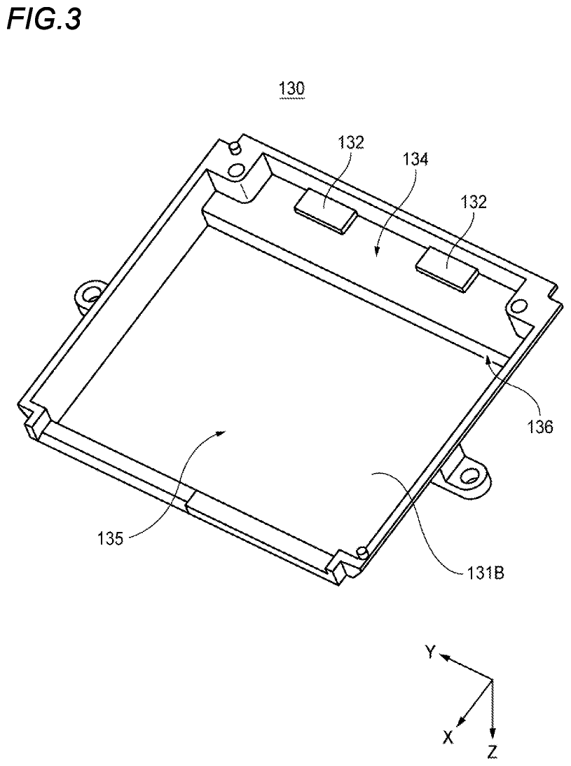

FIG. 2 is a view showing a configuration example of the information processing apparatus according to the present embodiment, and is a sectional view of the information processing apparatus as viewed from the left side (negative direction of the Y axis). FIG. 3 is a view showing a configuration example of a protective cover according to the present embodiment, and is a perspective view of the protective cover as viewed from a back side. Next, the information processing apparatus and the protective cover will be described in detail with reference to FIGS. 2 and 3.

The information processing apparatus 100 is, for example, an apparatus that performs settlement processing. However, the present embodiment is not limited to an information processing apparatus that performs settlement processing, and can be applied to various information processing apparatus that handle secret information.

The information processing apparatus 100 includes a card connector 110, a circuit board 120, a protective cover 130, and a protective board 150.

The card connector 110 is a flat, substantially rectangular parallelepiped electronic equipment into which the IC card 16 is inserted. In the card connector 110, a card slot 111 as an insertion opening of the IC card 16 is formed on the front face (face in the positive direction of the X axis). The card slot 111 corresponds to the slot 12 for settlement of the contact type IC card in FIG. 1. The card connector 110 reads information of the inserted IC card 16, and transmits the read information to an IC chip that performs settlement processing on the circuit board 120.

The circuit board 120 is a printed circuit board (PCB), and includes a printed wiring (not shown) and one or more electronic components on an top face. The card connector 110 is attached to the circuit board 120 as one of electronic components. An IC chip is attached to the circuit board 120 as an example of the electronic components. The IC chip may be a processor, a memory, and a communication IN (Interface), or a combination thereof. The tamper detection circuit 200 is attached to the circuit board 120 as one of the IC chips.

The tamper detection circuit 200 monitors a signal flowing through a tamper detection wiring, which will be described later, and detects a disconnection and a short circuit of the tamper detection wiring by the tamper. The tamper refers to a physical attack from the outside for the purpose of analyzing or falsifying secret information. An example of the tamper is a probing attack in which an elongated probe is inserted from the outside to analyze or falsify a signal. When a disconnection or a short circuit of the tamper detection wiring is detected, the tamper detection circuit 200 performs a process for preventing the analysis and falsification of the secret information. For example, the tamper detection circuit 200 stops the operation of the IC chip and erases the information in the memory. As a result, the tamper by the attacker can be prevented.

The circuit board 120 includes a tamper detection wiring (not shown) for tamper detection with respect to the circuit board 120. The tamper detection wiring is electrically connected to the tamper detection circuit 200.

The circuit board 120 includes one or more board-side contacts 121 behind a rear face (face in the negative direction of the X axis) of the card connector 110. The board-side contacts 121 are electrically connected to the tamper detection circuit 200.

The protective cover 130 is disposed on the main face of the circuit board 120 so as to cover the card connector 110 and the board-side contacts 121 on the circuit board 120. Hereinafter, in the description of the protective cover 130, a face away from the circuit board 120 is referred to as an top face 131A, and a face close to the circuit board 120 is referred to as a bottom face 131B.

The protective cover 130 includes the same number of cover-side contacts 132 as the board-side contacts 121 at positions on the bottom face (back face) 131B that is brought into contact with the board-side contacts 121 when disposed on the circuit board 120.

The protective cover 130 includes a tamper detection wiring (not shown) on the entire face. The tamper detection wiring may be a pattern that covers the entire face of the protective cover 130 in a snake shape with a signal stroke. The tamper detection wiring may be formed by a laser direct structuring (LDS) method. The tamper detection wiring is electrically connected to the cover-side contacts 132.

When the protective cover 130 is disposed on the circuit board 120, the cover-side contacts 132 are brought into contact with the board-side contacts 121. Thus, the tamper detection wiring of the protective cover 130 is electrically connected to the tamper detection circuit 200 through the cover-side contacts 132 and the board-side contacts 121. Therefore, the tamper detection circuit 200 can detect tamper with respect to the protective cover 130.

Further, when the protective cover 130 is detached from the circuit board 120, the cover-side contacts 132 are in non-contact (i.e., disconnected) with the board-side contacts 121, so that the tamper detection circuit 200 can also detect detachment of the protective cover 130.

That is, according to the above configuration in which the cover-side contacts 132 brought into contact with the board-side contacts 121 are provided on the bottom face (back face) 131B of the protective cover 130, both the tamper with respect to the protective cover 130 and the detachment of the protective cover 130 can be detected. In other words, both of the tamper with respect to the protective cover 130 and the detachment of the protective cover 130 can be detected with a small number of parts, and the tamper proof can be improved at a relatively low cost.

Further, an opening 133 larger than the opening of the card slot 111 is formed on a front end of the protective cover 130 such that the IC card 16 can be inserted into the card slot 111.

Therefore, a gap Q is formed between the top face 112 of the card connector 110 and the bottom face 131B of the protective cover 130. Therefore, the protective cover 130 has a shape such that the height hl from the top face of the circuit board 120 to a partial face (hereinafter referred to as “contact partial bottom face”) 134 of the bottom face 131B of the protective cover 130 including the cover-side contacts 132 is lower than the height h2 from the top face of the circuit board 120 to the top face 112 of the card connector 110.

That is, as shown in FIGS. 2 and 3, the protective cover 130 has a shape such that the contact partial top face 134 is one step lower than a partial face (hereinafter referred to as “connector partial bottom face”) 135 of the bottom face 131B of the protective cover 130 that covers the top face of the card connector 110 (closer to the top face of the circuit board 120). That is, the protective cover 130 has a step between the contact partial bottom face 134 and the connector partial bottom face 135.

Thus, as indicated by the dotted arrow B1 in FIG. 2, even if an attacker inserts an elongated probe into the gap Q from the opening 133 of the protective cover 130 and comes into contact with the cover-side contacts 132, the probe abuts against a stepped face 136 connecting the contact partial bottom face 134 and the connector partial bottom face 135. Therefore, the attacker cannot bring the probe into contact with the cover-side contacts 132 (and the board-side contacts 121).

The protective cover 130 may have a shape such that the height h3 from the top face of the circuit board 120 to the upper side of the opening 133 is lower than the height h2 from the top face of the circuit board 120 to the top face of the card connector 110. Accordingly, since the gap Q is shielded by the protective cover 130, the insertion of the probe with respect to the gap Q can be prevented.

The protective board 150 includes a tamper detection wiring (not shown). The tamper detection wiring is electrically connected to the tamper detection circuit 200. The protective board 150 is disposed to face above the contact partial bottom face 134 of the protective cover 130. Accordingly, when the attacker inserts the probe toward the cover-side contacts 132 of the protective cover 130 from above, the probe is detected by the protective board 150 before reaching the protective cover 130. That is, the tamper with respect to the cover-side contacts 132 can be prevented. Although not shown in FIG. 2, the protective board 150 is supported by, for example, a wall member extending upward (in the Z axis direction) from the circuit board 120 at any position.

The protective board 150 may be disposed in a space between a face (hereinafter referred to as a “contact partial top face”) 137 on an opposite side of the contact partial bottom face 134 of the protective cover 130 and a face (hereinafter, referred to as a “connector partial top face”) 138 on an opposite side of the connector partial bottom face 135 of the protective cover 130. As a result, the maximum height h4 of the information processing apparatus 100 is the height from the bottom face of the circuit board 120 to the connector partial top face 138 of the protective cover 130. That is, the thickness of the information processing apparatus 100 in the height direction (Z axis direction) can be reduced.

(Conclusion of Present Disclosure)

The information processing apparatus (100) according to the present disclosure includes: a card slot (111) that is arranged on a front of the information processing apparatus; a circuit board (120); and a flat card connector (110) that is mounted on a main face of the circuit board. A first contact (121) is provided on the main face of the circuit board, and is disposed behind the card connector. A cover (130) covers the card connector and the first contact on the circuit board. A second contact (132) is provided on a bottom face of the cover, and is in contact with the first contact. A tampering detection wiring is arranged on the cover, is a wiring for tampering detection, and is connected to the second contact. An opening (133) is formed at a front end of the cover lager than an opening of the card slot. The cover is shaped so that a height (h1) from the circuit board to an area with the second contact on the bottom face of the cover (contact partial bottom face 134) is lower than a height (h2) from the circuit board to a top face of the card connector.

According to this configuration, for example, even if an attacker inserts the elongated probe into the gap (Q) between the top face of the card connector (110) and the connector partial bottom face (135) which is the partial bottom face that covers the card connector of the cover from the opening (133) of the cover (130) and comes into contact with the cover-side contacts (132), the probe abuts against the stepped face (136) connecting the contact partial bottom face (134) and the connector partial bottom face (135) in the cover. Therefore, the attacker cannot bring the probe into contact with the second contact (132) (and the first contact (121)). Therefore, the tamper proof of the information processing apparatus (100) is improved.

The shape of cover (130) may be a shape such that the height (h3) from the top face of the circuit board (120) to the upper side of the opening (133) is lower than the height (h2) from the top face of the circuit board to the top face (112) of the card connector (110). That is, the size of the opening from the circuit board to the cover is smaller than the size (thickness) of the card connector from the circuit board to the top face of the card connector.

According to this configuration, since the gap (Q) between the top face of the card connector (110) and the bottom face (131B) of the cover is shielded by the cover from the opening (133) of the cover (130), insertion of the probe with respect to the gap can be prevented. Therefore, the tamper proof of the information processing apparatus (100) is improved.

The information processing apparatus (100) may further include a protective board (150) which is disposed to face above the contact partial bottom face (134) of the cover (130) and includes a tamper detection wiring.

According to this configuration, for example, when the attacker inserts the probe toward the second contact (132) of the cover (130) from above, the probe is detected by the protective board (150) before reaching the protective cover 130. That is, the tamper with respect to the second contact (132) can be prevented. Therefore, the tamper proof of the information processing apparatus (100) is improved.

The protective board (150) may be disposed in a space between an top face (137) on the opposite side of a contact partial bottom face and a partial top face (138) covering the card connector in the cover.

According to this configuration, the maximum height (h4) of the information processing apparatus (100) is the height from the bottom face of the circuit board (120) to the partial top face (138) covering the card connector. Therefore, the thickness of the information processing apparatus 100 in the height direction can be reduced.

Although the embodiments have been described above with reference to the accompanying drawings, the present disclosure is not limited to such examples. Those skilled in the art will recognize that various changes, modifications, substitutions, additions, deletions, and equivalents may be made within the scope of the appended claims, and are understood to belong to the technical scope of the present disclosure. In addition, constituent elements in the above-described embodiments may be arbitrarily combined within a range not departing from the gist of the invention.

### INDUSTRIAL APPLICABILITY

The technology of the present disclosure is useful in an apparatus that is required to be tamper proof.

What is claimed is:

1. An information processing apparatus comprising:
a card slot that is arranged on a front of the information processing apparatus;
a circuit board; and
a flat card connector that is mounted on a main face of the circuit board, wherein:
a first contact is provided on the main face of the circuit board, and is disposed behind the card connector,
a cover covers the card connector and the first contact on the circuit board,
a second contact is provided on a bottom face of the cover, and is in contact with the first contact,
a tampering detection wiring is arranged on the cover, is a wiring for tampering detection, and is connected to the second contact,
an opening is formed at a front end of the cover lager than an opening of the card slot, and
the cover is shaped so that a height from the circuit board to an area with the second contact on the bottom face of the cover is lower than a height from the circuit board to a top face of the card connector.

2. The information processing apparatus according to claim 1, wherein:
the cover is shaped so that a height in the opening from the circuit board to the bottom face of the cover is lower than the height in the card connector from the circuit board to a top face of the card connector.

3. The information processing apparatus according to claim 2, further comprising
a protective board that is arranged so as to face above the cover in which the second contact is located, and that has a tampering detection wiring.

4. The information processing apparatus according to claim 3, wherein:
the protective board is arranged in a space between a first top face of the cover opposite to the bottom face of the cover in the area with the second contact and a second top face of the cover in the area which covers the top face of the card connector.
